(19) United States
(12) Patent Application Publication
(10) Pub. No.: US 2025/0233605 A1
(43) Pub. Date: Jul. 17, 2025

(54) FILTER CIRCUITRY WITH HIGH HARMONIC SUPPRESSION

(71) Applicant: Qorvo US, Inc., Greensboro, NC (US)

(72) Inventors: Aykut Cihangir, Munich (DE); Asdesach Zena Markos, Munich (DE); Andreas Link, Laaber (DE)

(21) Appl. No.: 19/013,055

(22) Filed: Jan. 8, 2025

Related U.S. Application Data
(60) Provisional application No. 63/621,610, filed on Jan. 17, 2024.

(51) Int. Cl. H04B 1/04; H03H 9/54; H03H 9/70; H04B 1/10

(52) U.S. Cl. CPC H04B 1/0475; H03H 9/542; H03H 9/70; H04B 1/10

(57) ABSTRACT

Filter circuitry having harmonic blocking circuitry with a first blocking inductor coupled between a first blocking terminal and a second blocking terminal, and a first acoustic wave resonator coupled in parallel with the first blocking inductor, wherein the first blocking inductor and first acoustic resonator are configured to substantially attenuate harmonics of signals that pass between the first blocking terminal and the second blocking terminal. Further included is an acoustic wave filter bank having a plurality of first filter ports and a plurality of second filter ports. In some embodiments, the acoustic wave filter bank has at 10 least two second filter ports of the plurality of second filter ports multiplexed together and coupled to the first blocking terminal.

### RELATED APPLICATIONS

This application claims the benefit of provisional patent application Ser. No. 63/621,610, filed Jan. 17, 2024, the disclosure of which is hereby incorporated herein by reference in its entirety.

### FIELD OF THE DISCLOSURE

The present disclosure relates to radio frequency front-end circuitry configured to improve second harmonic suppression and reduce losses in transmit and receive paths.

### BACKGROUND

With the evolution of the mid-high-band (MHB) low-noise amplifier and duplexer (L-PAMID) architectures towards the use of multi-ON antenna switches and with the increase of the number of different carrier aggregation scenarios, it has become crucial that mid-band (MB) multiplexers such as the B1B3 quadplexer or the B25B66 quadplexer provide an impedance as high as possible for the high band frequencies at antenna switch bump.

Another important requirement for the MB transmit (TX) filters is to provide a very low second harmonic from the module, since the second harmonic for these filters overlaps with new generation Wireless Fidelity (Wi-Fi) bands that are also available on the same wireless communication device.

To overcome the tight second harmonic requirement, one option is to include a second harmonic (H2) trap at the post-antenna switch (between the antenna switch and the module OUT pin) that will apply to all MB TX filters in the module. However, this causes more loss in the higher frequencies (HB filters 2.5 GHz to 2.7 GHZ) that degrades the efficiency and noise figure for bands such as B7TX/RX or B41.

Another possibility is to use individual H2 traps in front of the MB TX filters, composed of a small inductor in parallel with a capacitor, to resonate at H2 frequencies and suppress the generated second harmonic. This method gives less impact in terms of loss and multiplexing, but the achieved suppression may be insufficient. Furthermore, the suppression may be very sensitive depending on the surface-mount device tolerances, and the architecture may require additional surface-mount devices, increasing the layout area usage and cost.

To overcome the foregoing two issues of the impact/loading from the MB multiplexer to HB filters and the H2 suppression from the MB TX filters, an efficient architecture and method are disclosed.

### SUMMARY

Filter circuitry having harmonic blocking circuitry with a first blocking inductor coupled between a first blocking terminal and a second blocking terminal, and a first acoustic wave resonator coupled in parallel with the first blocking inductor, wherein the first blocking inductor and first acoustic resonator are configured to substantially attenuate harmonics of signals that pass between the first blocking terminal and the second blocking terminal. Further included is an acoustic wave filter bank having a plurality of first filter ports and a plurality of second filter ports. In some embodiments, the acoustic wave filter bank has at least two second filter ports of the plurality of second filter ports multiplexed together and coupled to the first blocking terminal.

At least one alternative embodiment of the filter circuitry includes a second acoustic wave resonator and a second blocking inductor coupled in series between at least one of the first blocking terminal and the second blocking terminal and a fixed voltage node. Such configurations include a series path or both series and shunt paths to provide harmonic suppression and/or high band phasing.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic showing blocking circuitry according to the present disclosure.

FIG. 2 is a graph showing the impedance Zin characteristics of the blocking circuitry according to the present disclosure.

FIG. 3 is a graph showing the equivalent inductance of the blocking circuitry according to the present disclosure.

FIG. 4 is a simplified block diagram of a portion of a radio frequency front-end (RFFE) having filter circuitry with the blocking circuitry structured in accordance with the present disclosure.

FIG. 5 is a more detailed block diagram showing an exemplary embodiment of the RFFE portion having filter circuitry with the blocking circuitry structured in accordance with the present disclosure.

FIG. 6 is a schematic of an enhanced version of the blocking circuitry that is configured for additional harmonic suppression.

FIG. 7 is a block diagram of the RFFE portion wherein the resonator of the blocking circuitry is fabricated on its own semiconductor die.

FIG. 8 is a block diagram of the RFFE portion wherein the resonator of the blocking circuitry is integrated into a semiconductor die having another circuitry, such as high band circuitry.

FIG. 9 is a block diagram of the RFFE portion wherein the enhanced

version of the blocking circuitry of FIG. 6 is employed.

FIG. 10 is a graph showing an input impedance for a B40 implementation of the blocking circuitry.

FIGS. 11 and 12 are graphs showing results of a B40 implementation of the blocking circuitry resulting in loss improvement in B7.

FIG. 13 is a block diagram of a wireless device that employs the RFFE portion with filtering circuitry that includes the blocking circuitry structured in accordance with the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Embodiments according to the present disclosure achieve better harmonic suppression for the mid-band (MB) transmit (TX) filters, while providing better multiplexer loss both for the MB filters and high-band (HB) filters.

Although the example illustrations presented herein are based on the multi-on antenna switch configuration, the methodology can be applied to any case in which a MB multiplexer is multiplexed with some HB filters, including non- switchable MB-HB multiplexers or various antenna switch architectures in hybrid configuration with multiplexer switches.

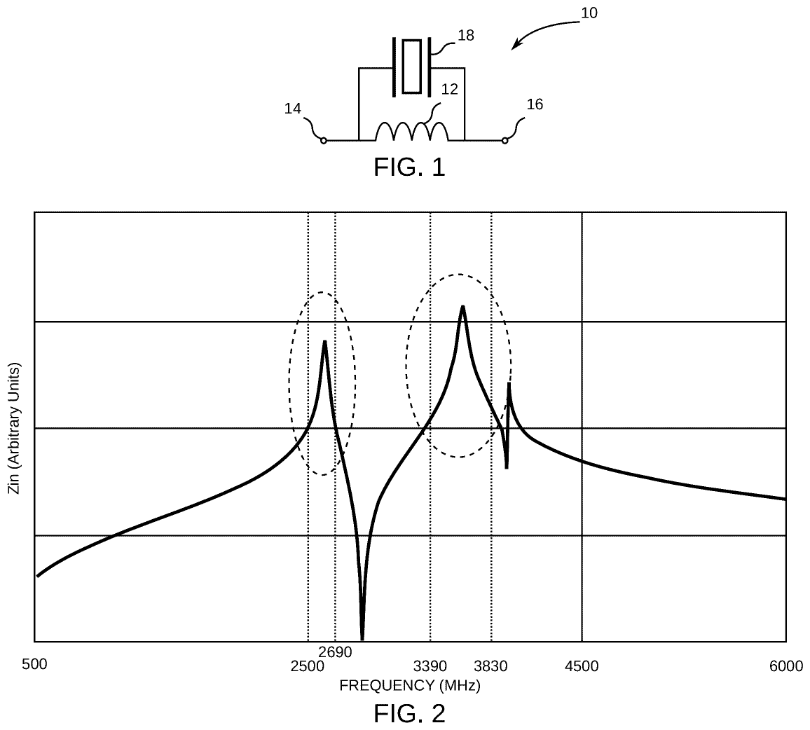

FIG. 1 is a schematic showing blocking circuitry 10 according to the present disclosure. The blocking circuitry 10 has a blocking inductor 12 that is coupled between a first blocking terminal 14 and a second blocking terminal 16. An acoustic wave resonator 18 is coupled in parallel with the inductor between the first blocking terminal 14 and the second blocking terminal 16. The acoustic wave resonator 18 may be a bulk acoustic wave resonator.

The blocking circuitry 10 exhibits an impedance Zin that provides a signal blocking behavior as shown in FIG. 2. As shown, the impedance of the blocking circuitry 10 generates a first anti-resonance shown within a first dashed oval enclosing 2500 MHz to 2690 MHz. The first anti-resonance occurs around the HB frequency range presenting a high impedance to external circuitry (not shown). The blocking circuitry 10 further provides a second anti-resonance, depicted in a second dashed oval enclosing 3390 MHz to 3830 MHz, at MB second harmonic (H2) frequencies that create a high H2 suppression.

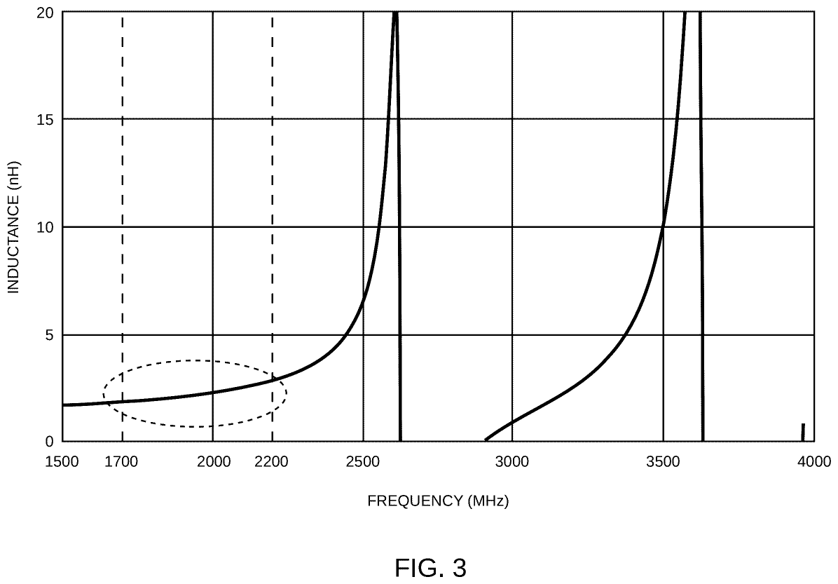

As depicted in FIG. 3, the blocking inductor 12 of the blocking circuitry 10 provides a series inductance for the MB frequencies. The inductance versus frequency graph of FIG. 3 shows the input inductance from the blocking inductor 12 provides a 2 nanohenries (nH) to 3 nH series inductance for the MB frequency ranges shown within a dashed oval enclosing 1700 MHz and 2200 MHZ. In yet other embodiments, the inductance values range between 0.5 nH and 5 nH.

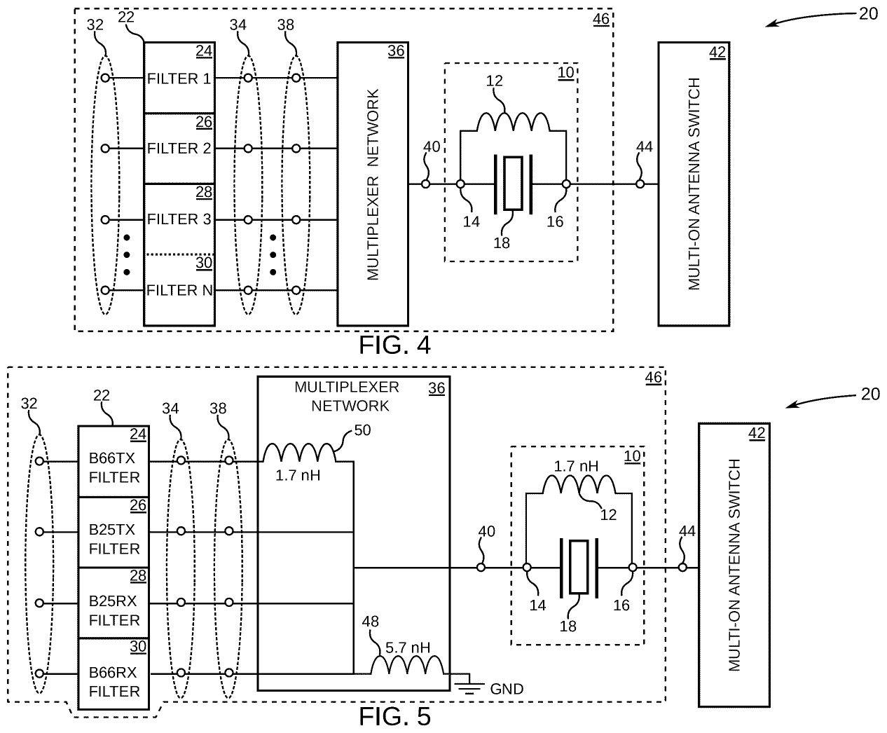

FIG. 4 is a simplified block diagram of a portion of radio frequency front-end (RFFE) circuitry 20 that is structured in accordance with the present disclosure to include the blocking circuitry 10. The portion of RFFE circuitry 20 includes a filter bank 22 made up of a first filter 24, a second filter 26, a third filter 28, and an Nth filter 30, wherein N is a natural counting number greater than one. Each of the first filter 24, the second filter 26, the third filter 28, and the Nth filter 30 has a corresponding one of first filter port terminals 32, and a corresponding one of second filter port terminals 34. A multiplexer network 36 has multiplexer port terminals 38 that are coupled to corresponding ones of the second filter port terminals 34. The multiplexer network 36 is configured to combine and/or split signals between the multiplexer port terminals 38 and a combined signal port terminal 40. In this exemplary embodiment, a multi-on antenna switch 42 is coupled to the multiplexer network 36 through the blocking circuitry 10. The first blocking terminal 14 is coupled to the combined signal port terminal 40, and an antenna switch terminal 44 of the multi-on antenna switch 42 is coupled to the second blocking terminal 16. An advantage of the blocking circuitry 10 is that it provides an inductive in-band impedance from the multi-on antenna switch 42 to the filter bank 22, through the multiplexer network 36, which is required for better complex conjugate matching for the filter bank 22. The blocking circuitry 10, the filter bank 22, and the multiplexer network 36 are combined to make up filter circuitry 46.

The properties of the blocking circuitry 10 serve at least two purposes:
higher impedance provided to HB frequencies: One advantage is less loading and lower loss in HB filters. Another advantage is that the multiplexer network 36 has a relatively simpler structure than standard multiplexer networks because HB phasing is covered by the blocking circuitry 10 according to the present disclosure (FIG. 4).
higher impedance at MB H2 frequencies: This provides higher H2 suppressions for MB TX bands such as B66TX and B25TX.
   An example implementation has been done with the circuitry according to the present disclosure and benchmarked versus known multiplexer solutions with multi-ON antenna switch architectures. The example topology incorporating the disclosed circuitry is depicted in FIG. 5. In this exemplary embodiment, the first filter 24 is a band 66 transmit (B66TX) filter, the second filter 26 is a band 25 transmit (B25TX) filter, the third filter 28 is a band 25 receive (B25RX) filter, and the Nth filter is a band 66 receive (B66RX) filter, where in this case N equals 4. Also, in this exemplary embodiment, a first multiplexer inductor 48 is coupled between the combined signal terminal 40 and a fixed voltage node GND, which in this case is ground. Moreover, in this exemplary embodiment, the first multiplexer inductor 48 is coupled between the first blocking terminal 14 and ground because the combined signal terminal 40 and the first blocking terminal 14 share a common node. In this case, an exemplary inductance value of 5.7 nH is chosen for the first multiplexer inductor 48.

A second multiplexer inductor 50 is coupled between the corresponding one of the output terminal 34 for the first filter 24 and the combined signal terminal 40. In this exemplary case, an exemplary inductance value of 1.7 nH is chosen for the second multiplexer inductor 50. An exemplary inductance value of 1.7 nH is also chosen for the blocking inductor 12 for the exemplary embodiment of the blocking circuitry 10 as depicted in FIG. 5.

Compared with other topology examples from standard implementations, the multiplexer network 36 is greatly simplified, which allows for smaller laminate area and more compact design overall.

Comparing the losses of multiplexer network 36 versus a known reference that is a B25B66 quadplexer, the HB filter losses such as for B7TX/RX and B41 are substantially reduced. Second harmonic (H2) suppression is also substantially improved compared with the reference.

Comparing the losses of multiplexer network 36 versus a known reference that is a B25B66 quadplexer, the multiplexer losses for the MB filters were also seen to be mostly improved. Another advantage is the increase of the impedances provided to the filters in filter bank 22, providing better complex conjugate matching.

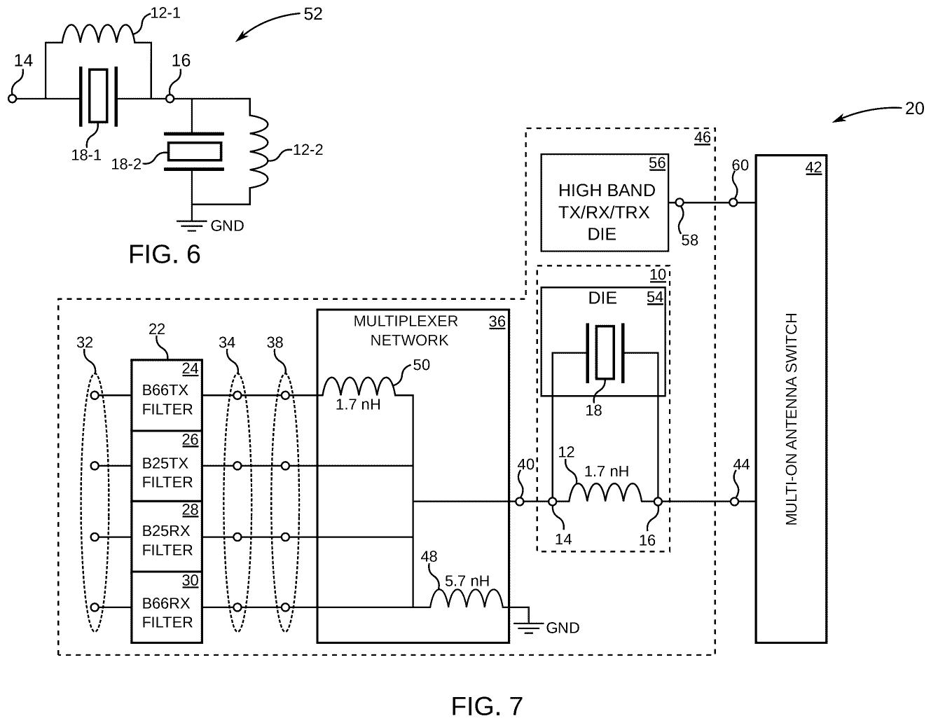

FIG. 6 is a schematic of an enhanced version of the blocking circuitry 10 that is configured for additional harmonic suppression. In this embodiment of an enhanced blocking circuitry 52, a series blocking inductor 12-1 is coupled between the first blocking terminal 14 and the second blocking terminal 16. A series acoustic wave resonator 18-1 is also coupled between the first blocking terminal 14 and the second blocking terminal 16, thereby placing the series blocking inductor 12-1 in parallel with the acoustic wave resonator 18-1. A shunt blocking inductor 12-2 is coupled in parallel with a shunt acoustic resonator 18-2 between the second blocking terminal 16 and the fixed voltage node GND. The enhanced blocking circuitry 52 depicted in FIG. 6 provides both series and shunt paths to increase the bandwidth of H2 suppression while having a negligible in-band trade-off.

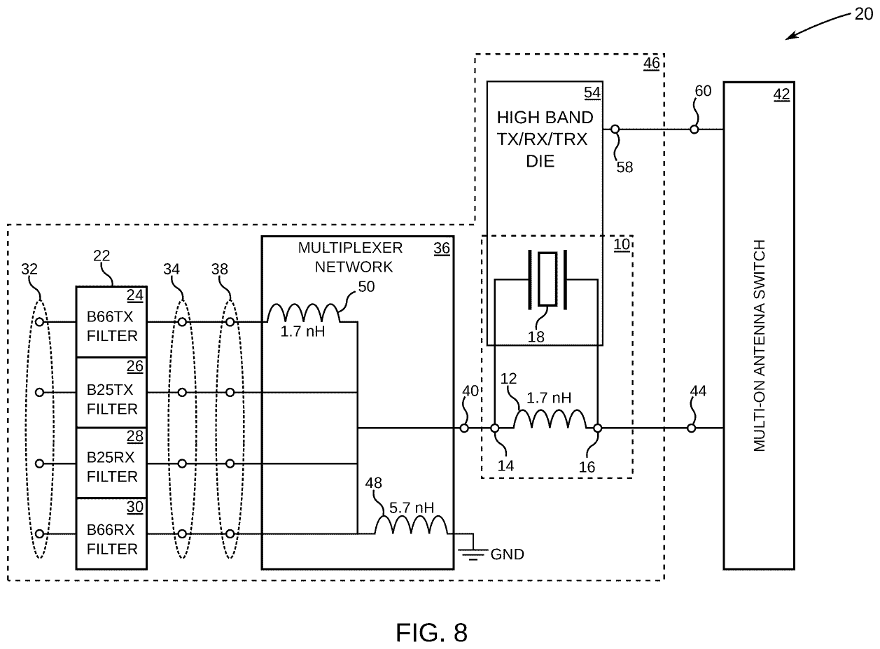

At least two types of implementations of the blocking circuitry 10 and the blocking circuitry 52 are possible. As depicted in FIG. 7, a relatively flexible solution is to have the acoustic wave resonator 18 as a separate die 54, which can be placed with convenience on a module. FIG. 7 further depicts a high band transit/receive/transmit-receive (TX/RX/TRX) die 56 that has an output terminal 58 coupled to a second antenna switch terminal 60. FIG. 8 depicts an alternative embodiment of the filtering circuitry 46 with less cost that places the acoustic wave resonator 18 inside one of the HB filter dies such as the high band TX/RX/TRX die 54.

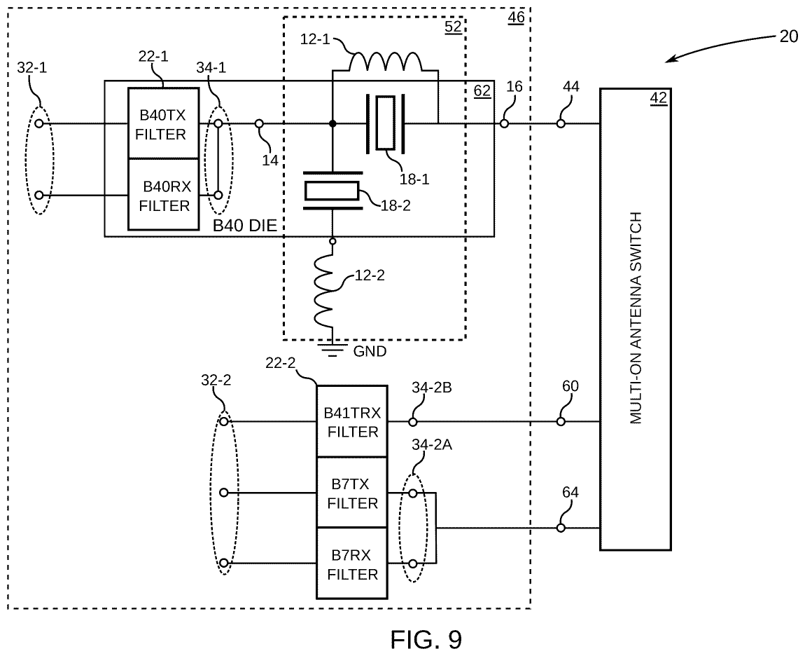

As depicted in an alternative embodiment of FIG. 9, the disclosed methodology may be employed in higher MB filters, such as B30 or B40, to reduce multiplexer network losses of HB filters. This methodology is particularly helpful when carriers are aggregated within bands, such as B40-B7 or B40-B41. In this configuration, the enhanced blocking circuitry 52 has the series acoustic wave resonator 18-1 and the shunt acoustic resonator 18-2 integrated in a B40die 62. In other embodiments, a single stage of blocking circuitry 10 may be employed in higher MB filters, such as B30 or B40, to reduce multiplexer network losses of HB filters. In the exemplary embodiment of FIG. 9, a first filter bank 22-1 is made up of a B40TX filter and a B40RX filter having first B40 filter port terminals 32-1 and second B40 filter port terminals 34-1 that are coupled together with the first blocking terminal 14. Moreover, the filter bank 22-1 may also be a B40TRX filter comprising a single filter as opposed to splitting B40TX and B40RX. A second filter bank 22-2 is made up of a B41TRX filter, a B7TX filter, and a B7RX filter having first B41/B7 filter port terminals 32-2 and second B41/B7 filter port terminals 34-2A and 34-2B. Corresponding ones of the second B41/B7 filter port terminals 34-2A are coupled together with a third antenna switch terminal 64. The other second B41/B7 filter port terminal 34-2B is coupled to the second antenna switch terminal 60. It is to be understood that desired filters in the second filter bank 22-2 may be configured for other desirable bands, and the B40 die may be dedicated to other desirable bands, thus the exemplary bands depicted in FIG. 9 do not limit the scope of the present disclosure.

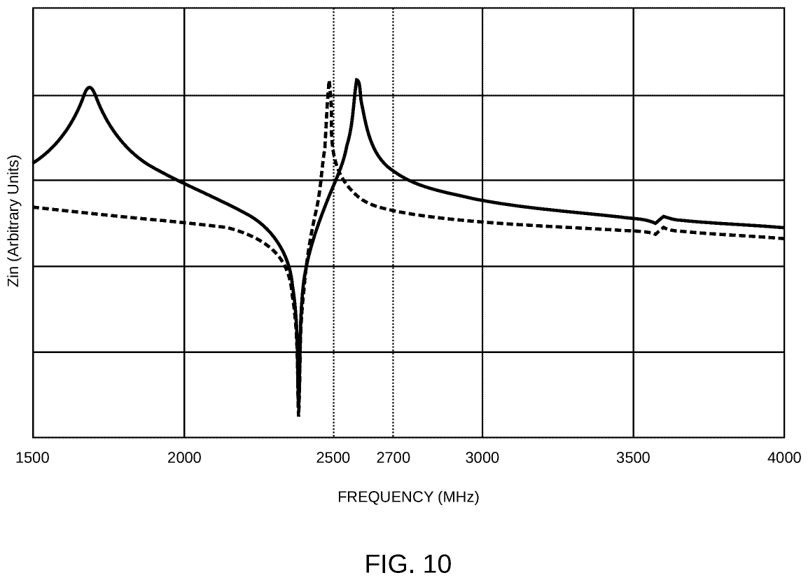

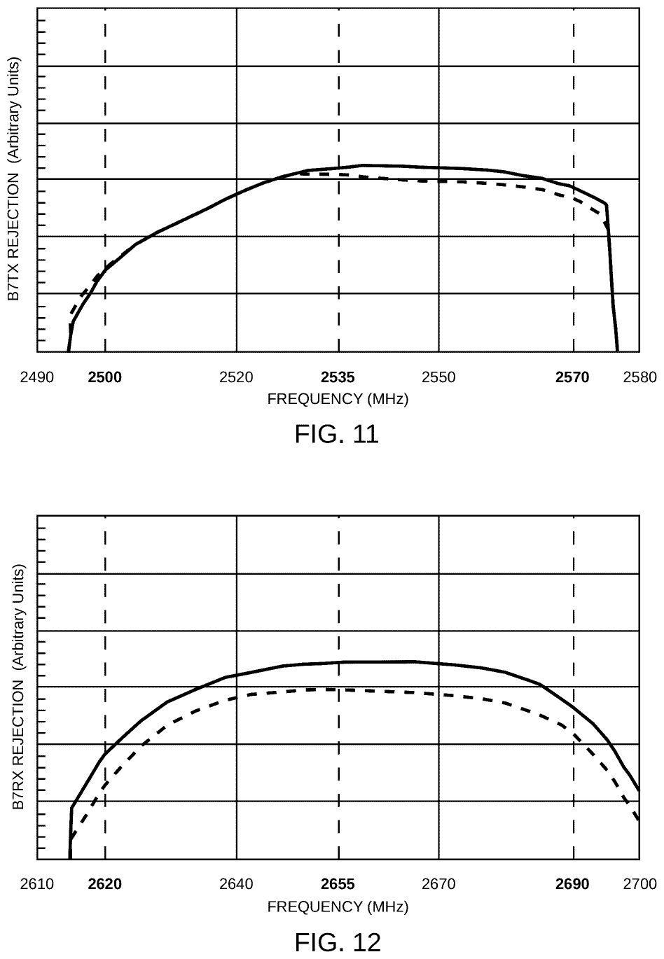

The corresponding input impedance characteristics of the circuitry can be seen in FIG. 10 in which a dashed line shows a standard series 1 resonator of B40 filter, wherein the series 1 resonator is the resonator closest to an antenna bump. A solid line shows performance with the disclosed blocking circuitry 52. FIG. 11 and FIG. 12 are graphs showing results of a B40 implementation of the blocking circuitry resulting in loss improvement in B7. The dashed lines in each graph depict original loss levels and the solid lines in each graph depict loss levels employing the blocking circuitry 52 as shown for the embodiment of FIG. 9. Reduced losses are observed in HB filter losses whenever the blocking circuitry 52 is employed. In general, either of the disclosed blocking circuitry 10 or blocking circuitry 52 serves for better HB loading and better H2 suppression in filtering circuitry 46 typically found in wireless communication devices. Moreover, the out-of-band impedance in the 2500-2690 MHz higher band depicted in the solid line demonstrates that less loading of HB filters is enabled.

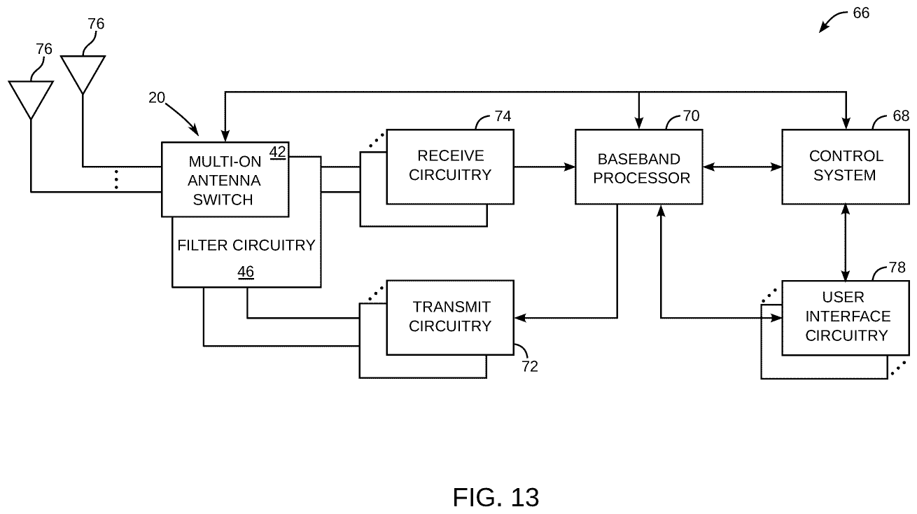

With reference to FIG. 13, the concepts described above may be implemented in various types of wireless communication devices or user elements 66, such as mobile terminals, smart watches, tablets, computers, navigation devices, access points, and the like that support wireless communications, such as cellular, wireless local area network (WLAN), Bluetooth, and near-field communications. The user elements 66 will generally include a control system 68, a baseband processor 70, transmit circuitry 72 associated with filter circuitry 46 that includes the blocking circuitry 10, receive circuitry 74, multiple antennas 76, user interface circuitry 78, and the RFFE circuitry 20 that includes the filter circuitry 46, and the multi-on antenna switch 42. The receive circuitry 74 receives radio frequency signals via the antennas 76 and through the multi-on antenna switch 42 from one or more basestations. A low-noise amplifier and a filter (not shown) cooperate to amplify and remove broadband interference from the received signal for processing. Downconversion and digitization circuitry (not shown) then downconvert the filtered, received signal to an intermediate or baseband frequency signal, which is then digitized into one or more digital streams.

The baseband processor 70 processes the digitized received signal to extract the information or data bits conveyed in the received signal. This processing typically comprises demodulation, decoding, and error correction operations. The baseband processor 70 is generally implemented in one or more digital signal processors (DSPs) and application-specific integrated circuits (ASICs).

For transmission, the baseband processor 70 receives digitized data, which may represent voice, data, or control information, from the control system 68, which it encodes for transmission. The encoded data are output to the transmit circuitry 72, where they are used by a modulator (not shown) to modulate a carrier signal that is at a desired transmit frequency or frequencies. A power amplifier (not shown) amplifies the modulated carrier signal to a level appropriate for transmission and delivers the modulated carrier signal to the antennas 76 through the multi-on antenna switch 42. The antennas 76 and the replicated transmit circuitry 72 and receive circuitry 74 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. Filter circuitry comprising:
blocking circuitry having a first blocking inductor coupled between a first blocking terminal and a second blocking terminal, and a first acoustic wave resonator coupled in parallel with the first blocking inductor, wherein the first blocking inductor and first acoustic resonator are configured to substantially attenuate harmonics of signals that pass between the first blocking terminal and the second blocking terminal; and
an acoustic wave filter bank having a plurality of first filter ports and a plurality of second filter ports.

2. The filter circuitry of claim 1 wherein the harmonics are second harmonics.

3. The filter circuitry of claim 1 further comprising a second acoustic wave resonator and a second blocking inductor coupled in series between at least one of the first blocking terminal and the second blocking terminal and a fixed voltage node.

4. The filter circuitry of claim 3 wherein the first acoustic resonator and the second acoustic resonator are fabricated on a semiconductor die.

5. The filter circuitry of claim 1 wherein the acoustic filter bank has at least two second filter ports of the plurality of second filter ports multiplexed together and coupled to the first blocking terminal.

6. The filter circuitry of claim 5 further comprising a multiplexer network coupled between the plurality of second filter ports of the acoustic wave filter bank and the first blocking terminal of the blocking circuitry.

7. The filter circuitry of claim 6 wherein the multiplexer network has a first multiplexer inductor coupled between the first blocking terminal of the blocking circuitry and ground.

8. The filter circuitry of claim 7 wherein the multiplexer network has at least a second multiplexer inductor coupled between at least one of the at least two second filter ports of the plurality of second filter ports and the first blocking terminal of the blocking circuitry.

9. The filter circuitry of claim 1 wherein the first acoustic wave resonator is fabricated on a semiconductor die.

10. The filter circuitry of claim 9 wherein the semiconductor die is configured for at least one of the low band, the medium band, and the high band of long-term evolution frequency spectrum.

11. A method of operating filter circuitry having a first acoustic wave resonator coupled in parallel with a first blocking inductor coupled between a first blocking terminal and a second blocking terminal and an acoustic wave filter bank having a plurality of first filter ports and a plurality of second filter ports, wherein the acoustic wave filter bank has at least two second filter ports of the plurality of second filter ports coupled to the first blocking terminal, the method comprising:
selecting an inductance value of the first blocking inductor and a resonant frequency of the first acoustic wave filter that will substantially attenuate undesirable harmonics of select signals passing through the filter circuitry; and
multiplexing signals passing through the at least two second filter ports of the plurality of second filter ports together by way of a multiplexing network.

12. The method of operating filter circuitry of claim 11 further comprising selecting a resonator area of the first acoustic wave filter that will further substantially attenuate undesirable harmonics of select signals passing through the filter circuitry.

13. The method of operating filter circuitry of claim 11 wherein the undesirable harmonics of signals passing through the filter circuitry are second harmonics.

14. The method of operating filter circuitry of claim 11 further comprising coupling a second acoustic wave resonator and a second blocking inductor in series between at least one of the first blocking terminal and the second blocking terminal and a fixed voltage node.

15. The method of operating filter circuitry of claim 14 further comprising selecting an inductance value of the second blocking inductor and a resonant frequency of the second acoustic wave filter that will further substantially attenuate undesirable harmonics of signals passing through the filter circuitry.

16. The method of operating filter circuitry of claim 15 further comprising selecting a resonator area of the first acoustic wave filter that will further substantially attenuate undesirable harmonics of select signals passing through the filter circuitry.

17. The method of operating the filter circuitry of claim 14 wherein the fixed voltage node is ground.

18. A wireless communication device comprising:
receive circuitry configured to receive radio frequency (RF) signals;
a baseband processor configured to process a digitized version of the RF signals received by the receive circuitry and to extract the information or data bits conveyed in the received RF signals;
transmit circuitry configured to receive encoded data from the baseband processor and to modulate a carrier signal with the encoded data; and
filter circuitry that is coupled to the receive circuitry and transmit circuitry, the filter circuitry comprising;
blocking circuitry having a first blocking inductor coupled between a first blocking terminal and a second blocking terminal, and a first acoustic wave resonator coupled in parallel with the first blocking inductor, wherein the first blocking inductor and first acoustic wave resonator are configured to substantially attenuate harmonics of signals that pass between the first blocking terminal and the second blocking terminal; and
an acoustic wave filter bank having a plurality of first filter ports and a plurality of second filter ports.

19. The wireless communication device of claim 18 wherein the harmonics are second harmonics.

20. The wireless communication device of claim 18 wherein the filter circuitry further comprises a second acoustic wave resonator and a second blocking inductor coupled in series between at least one of the first blocking terminal and the second blocking terminal and a fixed voltage node.

21. The wireless communication device of claim 20 wherein the first acoustic resonator and the second acoustic resonator are fabricated on a semiconductor die.

22. The wireless communication device of claim 18 wherein the acoustic wave filter bank has at least two second filter ports of the plurality of second filter ports multiplexed together and coupled to the first blocking terminal.

23. The wireless communication device of claim 22 wherein the filter circuitry further comprises a multiplexer network coupled between the second filter ports of the acoustic wave filter bank and the first blocking terminal of the blocking circuitry.

24. The wireless communication device of claim 23 wherein the multiplexer network has a first multiplexer inductor coupled between the first blocking terminal of the blocking circuitry and ground.

25. The wireless communication device of claim 24 wherein the multiplexer network has at least a second multiplexer inductor coupled between at least one of the at least two second filter ports of the plurality of second filter ports and the first blocking terminal of the blocking circuitry.

26. The wireless communication device of claim 18 wherein the first acoustic wave resonator is fabricated on a semiconductor die.

27. The wireless communication device of claim 26 wherein the semiconductor die is configured for at least one of the low band, the medium band, and the high band of long-term evolution frequency spectrum.
